(19) United States
(12) Patent Application Publication
(10) Pub. No.: US 2026/0116741 A1
(43) Pub. Date: Apr. 30, 2026

(54) MEMS Optical Modulator Independently Controlled with Integrated ASIC Device and Making the Same

(71) Applicant: SD OPTICS, INC., SEOUL (KR)

(72) Inventors: JIN YOUNG SOHN, SEOUL (KR); MIN BEOM LEE, SEOUL (KR); HONG JU KIM, SEOUL (KR); KYUNG PYO HONG, SEOUL (KR); GYOUNG IL CHO, Seoul (KR); CHEONG SOO SEO, Seoul (KR)

(21) Appl. No.: 18/932,500

(22) Filed: Oct. 30, 2024

(51) Int. Cl. B81B 7/02; G02B 26/08; G02F 1/295

(52) U.S. Cl. CPC B81B 7/02; G02B 26/0841; G02F 1/295; B81B 2201/042; B81B 2203/04; B81B 2203/06; B81B 2207/03; B81B 2207/07

(57) ABSTRACT

The present invention introduces the ASIC integrated MEMS device with exposed bond-pads from bottom attached ASIC and method for making the same. The ASIC integrated MEMS device with exposed bond-pads from bottom attached ASIC can be especially used for micromirror array MEMS devices. With the present invention and technology, individually controlling of thousands of micromirrors becomes possible and bring easier fabrication method. With the present invention and technology, individually controllable micromirror array can implement easier control method and more compact packing becomes feasible. With help of the present invention scheme, more complicated light modulating device scheme can be implemented with micromirror array or MEMS device with a large number of controlling channels. Scheme, apparatus, and method are disclosed in the present invention.

### FIELD OF THE INVENTION

The present invention relates to general MEMS (Micro-Electro Mechanical Systems) optical modulator with large number of degrees of freedom motion as well as independently controlled micromirrors in the MEMS optical modulator. Independent control of the MEMS optical modulator is achieved by the integrated ASIC (Application Specific Integrated Circuits) device wherein the MEMS optical modulator and the ASIC device are wafer-bonded while fabricated.

### BACKGROUND OF THE INVENTION

There are lots of optical modulators to manipulate the incident light to control light intensity, phase, and beam quality as well as beam direction. Even a lens can be an optical light modulator to have focusing property. But to modulate light in time, there should be a time-varying part of the modulator. With micromirror devices, there are many light modulators in market. Most famous one is DMD (Digital Micromirror Device) for display. Each pixel (section) is controlled to have on/off signal in time to display image information for projectors and displays. Beam steering mirror is another good example for an optical modulator. With proper beam stop or collecting the beam steering mirror also can be a good light intensity modulator based on collecting efficiency of the optical system.

There are sometimes multi-channel optical modulators to control light not only modulate intensity of the light but also modulate the property of the light. With micromirror, deformable mirrors work for optical phase control of the incident light. To control fine tuning, it is required to have more channels with independent control. Especially for micromirror applications, more channel access and control is a long time requirement but technical difficulties (especially size of the device and connection to the control circuit) hindered the usage of the multi-channel independently controllable micromirrors more than on/off control.

To have multiple channel of control for micromirror devices, there were many challenges for increment of the control channels.

For optical light modulators, specially MEMS (Micro-Electro Mechanical System) devices have been studied a lot. MEMS optical modulators have advantage of its size for controlling light even in wavelength dimension and easy electrical control was one of the strongest point of the MEMS optical modulators. But control circuit and MEMS device were not compatible with each other due to difference of fabrication process. MEMS optical modulators can be built but implementing control circuit was always difficult. Since the MEMS optical modulators can have only moving parts with simple wire structures, MEMS optical modulators are usually controlled from outside of the MEMS optical modulators. Since the controller of the MEMS optical modulators are located outside, connection to the MEMS optical modulators is another disadvantage of the device. Even many channels of control are required and outside controller has enough channels of control, the connection is a problem to a MEMS optical modulator due to its miniaturized size.

The typical system configuration of MEMS optical modulators and control logic circuit (prior art) is presented in the FIG. 1. The MEMS optical modulator (structures) is fabricated on a MEMS wafer substrate by use of MEMS and semiconductor processes. To establish a connection with the control logic circuit, the MEMS wafer substrate is attached onto control PCB together with the control logic circuit. In order to control the MEMS optical modulator, connections between the control logic circuit and the MEMS optical modulator are necessary. The bonded wires between the control logic circuit and the MEMS optical modulator supply control signals and power to MEMS optical modulator. For control by using a PC or a controller, external wire bonding is performed to supply control signal data and power from external source and controller. Further connectors can be installed through the control PCB. The typical configuration gives simple connections from MEMS optical modulator to PCB and control circuit ICs. The number of channels of the wire-bonding is limited due to size of the MEMS device. In general, the connection with the CMOS circuit for driving MEMS is established using wire bonding, as shown in FIG. 1. However, with the increasing research and development of MEMS devices and the growing applications, the operation of MEMS devices has become more complex, requiring numerous control channels to accommodate various modes of operation and degrees of freedom, as shown in FIG. 2.

FIG. 2 shows more complicated connection and stacking MEMS device on top of the control device such as CMOS logic circuit and controller ICs. The MEMS structures consisting of hundreds to thousands of micromirrors to be controlled independently can be fabricated for a MEMS optical modulator (wafer level). The fabricated and diced MEMS optical modulator can be bonded onto control PCB, together with MEMS control device (here mostly ASIC control device). Wire bonding is performed between the MEMS optical modulator and MEMS control device to provide control signal to the individual MEMS structures through the MEMS optical modulator input connections. With this structure, more connection in a smaller area could be achieved than the previous case. Still connecting with wire-bonding is a bottleneck of the device for having many channels.

To overcome these difficulties, Texas Instruments and Fraunhofer have adopted a method for producing a micromirror array device by directly stacking MEMS structures on top of a CMOS wafer, as shown in FIG. 3A in U.S. Pat. No. 9,950,924 B2 issued Apr. 24, 2018 to Sridharamurthy, U.S. Pat. No. 8,541,850 B2 issued Sep. 24, 2013 to Gupta, and U.S. Pat. No. 9,546,090 B1 issued Jan. 17, 2017 to Xia. Since MEMS structures are deposited directly on the CMOS circuit wafer, there is no need for wire bonding, enabling a rapid electrical transmission speed could be achieved. In DMD device in FIG. 3A and FIG. 3B in U.S. Pat. No. 5,583,688 issued Dec. 10, 1996 in Hornbeck, this wire-bonding issue is not a problem anymore. DMD device solved this wire-bonding issue with integrating CMOS circuit underneath the micromirror MEMS structures. Actually MEMS micromirror structures are built on top of the CMOS control circuit. Still DMD device has a restriction with only bi-stable motion (on/off) control and some MEMS processes are not compatible with the underlying CMOS structures. For example, Si surface micro-machined MEMS processes cannot be used after CMOS process since Si surface micromachining uses higher temperature than CMOS processes. Thus only low temperature MEMS process like Al—Cu alloy can be used in processes for DMD device. To overcome this constraints, the present invention of the MEMS optical modulator proposes a process with separate fabrication of MEMS wafer and ASIC device wafer and wafer-bonding together. With the idea of the present invention of the MEMS optical modulator with independently controlled with integrated ASIC device, the present invention of the MEMS optical modulator can overcome the limitation of the wire-connections for the MEMS device and the control circuitry.

Micromirror systems from Frauhofer group implement 1-axis tilting micromirrors that rotate around a central axis, 2-axis tilting micromirrors capable of tilting in any direction around a central axis, and piston motion micromirrors that transforms in the direction perpendicular to the micromirror surface. These micromirrors are used for the applications in adaptive optics and the field of wavefront correction, where individual control of the angles of millions of micromirrors is necessary. Fraunhofer has designed multiple drivers and controllers to secure an adequate number of I/O channels for individual angle control. However, the drawback arises from the need to assemble numerous drivers and controllers, leading to constraints in space and cost.

Direct deposition of MEMS structures on top of CMOS wafer, as applied by Texas Instruments and Fraunhofer, can eliminate the wire bonding process and easier access to the channels of the micromirror device, resulting in faster electrical transfer, lower costs, and greater convenience. The main difficulty of the MEMS-CMOS integration process in wafer level with these advantages was fabrication temperature. CMOS devices are typically at relatively low temperature between 15° and 400° C. for the semiconductor processes. If the CMOS device undergoes above 400° C., the device performance would be seriously degraded, described in U.S. Pat. No. 9,343,668 B2 issued May 17, 2016 to MaxWell. Therefore, in order to deposit MEMS structures at these process temperatures, it is necessary to deposit metallic (Cu, Ni, Ti, etc.) MEMS only with relatively low process temperatures (under 400° C.) in U.S. Pat. No. 9,630,834 B2 issued Apr. 24, 2017 to Tayebi.

Generally, materials such as metals, ceramics, and polysilicon are widely used in the deposition of MEMS structures. Polysilicon offers superior electrical and mechanical characteristics, and its high melting point compared to metals provides the advantage of stable operation. However, the processing temperature for polysilicon typically requires a minimum of around 580° C. and can go up to approximately 1000° C. in U.S. Pat. No. 9,006,016 B2 issued Apr. 14, 2015 to Celik-Butler, U.S. Pat. No. 10,071,905 B2 issued Sep. 11, 2018 to Chu. Due to high processing temperature, the stability of CMOS circuits cannot be insured. Thus, strong demand for a MEMS-CMOS integrated method that allows the use of polysilicon is increasing, which exhibits excellent characteristics as a MEMS material also.

In the present invention of the MEMS optical modulator with independently controlled with integrated ASIC device, the MEMS micromirror array device and the semiconductor ASIC device are fabricated separately at wafer level. Those separately fabricated wafers are wafer-bonded together with wafer-bonding technology. In the present invention, the ASIC device in the wafers is capable of controlling multiple channels. Before wafer bonding while fabricating MEMS structures, fine holes (via) penetrating the MEMS wafer vertically are formed. The TSV (through silicon via) method is applied here, wherein the holes are filled with a conductive material to establish a direct electrical connection pathway within the wafer, securing electrical connectivity and surroundings are insulated through the insulating layers around the TSVs in U.S. Pat. No. 10,833,052 B2 issued Nov. 10, 2020 to Shih, U.S. Pat. No. 9,997,497 B2 issued Jun. 12, 2018 to Yu. The TSV method provides a direct connection pathway through the MEMS wafer, eliminating the need for wire bonding of multiple electrodes to the semiconductor control ASIC wafers. This can eliminate the limitations of the number of I/O channels and problems like short circuits and contact defects. However, while TSV enables the connection between the electrodes of MEMS structures and the semiconductor control ASIC, bond pads are still necessary to supply the control signal data and power required for the control of the semiconductor control ASIC, thus MEMS structures through TSVs usually semiconductor control ASIC is wafer-bonded underneath the MEMS wafer.

To overcome the disadvantages of the previous technologies, the present invention introduces the present invention of the MEMS optical modulator with independently controlled with integrated ASIC device and method for operating the same. The MEMS optical modulator with independently controlled with integrated ASIC device can be especially utilized in the fields of micromirror array MEMS devices. With the present invention and technology, individually controlling of thousands of micromirrors becomes possible and bring easier fabrication method. With the present invention and technology, individually controllable micromirror array can implement easier control method and more compact packaging becomes feasible. Example and its application of the individually controllable micromirror array is described in the U.S. patent application Ser. No. 18/384,721 filed Oct. 27, 2023, which is incorporated herein by references.

### SUMMARY OF THE INVENTION

The present invention of the MEMS optical modulator with independently controlled with integrated ASIC device presents a method for operating MEMS optical modulator (especially micromirror array device) with a large number of degrees of freedom motion and a high number of independent control channels. The prior art technology increased and expanded its controllability of MEMS devices but not enough for the spatial light modulator with large number of control channels as well as large number of degrees of freedom motions for individual micromirrors in the micromirror array device.

The subjective matter of the present invention of the MEMS optical modulator with independently controlled with integrated ASIC device is utilizing MEMS fabrication technology and semiconductor control IC building technology separately and combining the MEMS wafer and control IC (ASIC) together with wafer-bonding method. Also the present invention of the MEMS optical modulator with independently controlled with integrated ASIC device utilizes TSV technology for connecting MEMS electrodes for controlling micromirrors and ASIC control electrodes. Especially for MEMS device, large amount of the surface of the substrate should be used for actuator electrodes. This actuator area prevents from connecting from the top surface of the MEMS devices. By use of TSVs, MEMS device could have connecting means in the bottom of the MEMS substrate rather than in the top of the MEMS substrate.

Once MEMS device has connecting means at the bottom of the substrate, it can be bonded with ASIC device substrate. Also ASIC device has electrodes to connect with MEMS device. Preferably, the electrodes of the MEMS device and the electrodes of the ASIC device are aligned together for direct connection between them. With current scheme of the present invention, the ASIC device can have a plurality of the electrodes on top of its substrate and the MEMS device can have a plurality of the electrodes. Considering MEMS TSV technology and wafer-bonding technology, thousands and tens of thousands connections can be built through the MEMS substrate and the wafer bonding within small size of MEMS device.

With the help of the present invention of the MEMS optical modulator with independently controlled with integrated ASIC device scheme, the MEMS optical modulator can generate free form surface with independently controlled micromirrors. Each micromirror in the MEMS optical modulator of the present invention has at least the same number of the actuators as the degrees of freedom motion. For micromirrors in the present invention have three degrees of freedom motion. Two degrees of freedom motion give tip and tilt (rotations) for the micromirror and one degree of freedom motion gives piston motion (translation) for the light modulation. Two degrees of freedom rotation motion bends light to the desire direction and the one degree of freedom translation motion can adjust and control the phase of the incident.

The present invention of the MEMS optical modulator with independently controlled with integrated ASIC device can modulate indent light with individual micromirrors and with motion degrees of freedom for the micromirrors. Especially, if the present invention of the MEMS optical modulator with independently controlled with integrated ASIC device is used with wavefront sensor, the present invention of the MEMS optical modulator can work as wavefront controlling deformable mirror. And if the present invention of the MEMS optical modulator with independently controlled with integrated ASIC device is controlling the surface for compensating the aberration of the optical system, it can be used as an optical aberration correction device. The present invention of the MEMS optical modulator with independently controlled with integrated ASIC device can be used specially for the fine tuning of the light control for many optical applications.

One of good example of the light modulating device is a Micromirror Array Lens, which modulates incident light to change optical focal length of the optical system. The general principle and methods for making the Micromirror Array Lens are disclosed in U.S. Pat. No. 6,970,284 issued Nov. 29, 2005 to Kim, U.S. Pat. No. 7,031,046 issued Apr. 18, 2006 to Kim, U.S. Pat. No. 6,934,072 issued Aug. 23, 2005 to Kim, U.S. Pat. No. 6,934,073 issued Aug. 23, 2005 to Kim, U.S. Pat. No. 7,161,729 issued Jan. 9, 2007 to Kim, U.S. Pat. No. 6,999,226 issued Feb. 14, 2006 to Kim, U.S. Pat. No. 7,095,548 issued Aug. 22, 2006 to Cho, U.S. Pat. No. 7,239,438 issued Jul. 3, 2007 to Cho, U.S. Pat. No. 7,267,447 issued Sep. 11, 2007 to Kim, U.S. Pat. No. 7,274,517 issued Sep. 25, 2007 to Cho, and U.S. Pat. No. 7,777,959 issued Aug. 17, 2010 to Sohn, U.S. Pat. No. 7,489,434 issued Feb. 10, 2009 to Cho, U.S. Pat. No. 7,619,807 issued Nov. 17, 2009 to Back, all of which are incorporated herein by references.

The general principle, structure and methods for making the micromirror array devices and Micromirror Array Lens are disclosed in U.S. Pat. No. 7,382,516 issued Jun. 3, 2008 to Seo, U.S. Pat. No. 7,330,297 issued Feb. 12, 2008 to Noh, U.S. Pat. No. 7,898,144 issued Mar. 1, 2011 to Seo, U.S. Pat. No. 7,474,454 issued Jan. 6, 2009 to Seo, U.S. Pat. No. 7,777,959 issued Aug. 17, 2010 to Sohn, U.S. Pat. No. 7,365,899 issued Apr. 29, 2008 to Gim, U.S. Pat. No. 7,589,884 issued Sep. 15, 2009 to Sohn, U.S. Pat. No. 7,589,885 issued Sep. 15, 2009 to Sohn, U.S. Pat. No. 7,400,437 issued Jul. 15, 2008 to Cho, U.S. Pat. No. 7,488,082 issued Feb. 10, 2009 to Kim, and U.S. Pat. No. 7,535,618 issued May 19, 2009 to Kim, U.S. Pat. No. 7,605,964 issued Oct. 20, 2009 to Gim, U.S. Pat. No. 7,411,718 issued Aug. 12, 2008 to Cho, U.S. Pat. No. 9,505,606 issued Nov. 29, 2016 to Sohn, U.S. Pat. No. 8,622,557 issued Jan. 7, 2014 to Cho, U.S. Pat. Pub. No. 2009/0303569 A1 published Dec. 10, 2009 to Cho, all of which are incorporated herein by references.

In Summary, (1) the MEMS optical modulator with independently controlled with integrated ASIC device can have a large number of individual control for highly populated MEMS control circuits. (2) The MEMS optical modulator with independently controlled with integrated ASIC device can have a virtually unlimited number of control channels for micromirror array MEMS systems. (3) The MEMS optical modulator with independently controlled with integrated ASIC device can provide easy light modulation method controlling directions and optical phase independently. (4) The MEMS optical modulator with independently controlled with integrated ASIC device can control section by section as a light modulator, which can be selected independently with other control. (5) The MEMS optical modulator with independently controlled with integrated ASIC device can provide an easier electrical connection method to the MEMS device with a large number of individually control channels. (6) The MEMS optical modulator with independently controlled with integrated ASIC device can provide much simpler and compact control method for the multi-channel MEMS devices. (7) The MEMS optical modulator with independently controlled with integrated ASIC device can be controlled with a simple control scheme since the integrated ASIC does generate the control voltages for the MEMS device. (8) The MEMS optical modulator with independently controlled with integrated ASIC device provides an approach for mass production through wafer level packaging method rather than individual device level, which can be a breakthrough for the highly populated multi-channel MEMS devices.

Although the present invention is briefly summarized, the full understanding of the invention can be obtained by the following drawings, detailed descriptions, and appended claims.

### DESCRIPTION OF FIGURES

These and other features, aspects and advantages of the present invention will become better understood with reference to the accompanying drawings, wherein

FIG. 1 illustrates general connection configuration of MEMS optical modulator and control logic circuit ICs and PCBs (prior art);

FIG. 2 illustrates general configuration of complex wire bonding connecting MEMS optical modulator with control circuits, and controllers (prior art);

FIG. 3A illustrates structure of Texas Instrument DMD device layer by layer (prior art);

FIG. 3B illustrates structure of Texas Instrument DMD device operation schematics (prior art);

FIG. 4 illustrates the bonded structure of the MEMS optical modulator with the ASIC device and arranged with square shape micromirror geometry wherein the MEMS electrodes and the ASIC electrodes are aligned with each other through TSV structures;

FIG. 5 illustrates the bonded structure of the MEMS optical modulator with the ASIC device and arranged with hexagonal shape micromirror geometry wherein the MEMS electrodes and the ASIC electrodes are aligned with each other through TSV structures;

FIG. 6 illustrates surface modulation of the optical modulator with square micromirrors;

FIG. 7 illustrates surface modulation of the optical modulator with hexagonal micromirrors;

FIG. 8 illustrates the package of the MEMS optical modulator with freeform motion and integrated ASIC device to control MEMS optical modulator, shows electrical connections;

FIG. 9 illustrates the cross sectional view of the optical modulator package wherein the MEMS optical modulator and the ASIC device connections with TSVs wherein the MEMS optical modulator and the ASIC device are wafer-bonded while fabricated;

FIG. 10 illustrates operation of MEMS optical modulator wherein individual micromirrors are operated independently (square micromirror arrangement);

FIG. 11 illustrates operation of MEMS optical modulator wherein individual micromirrors are operated independently (hexagonal micromirror arrangement);

FIG. 12 illustrates control steps of the MEMS optical modulator wherein data receiving and refreshing frame are performed in parallel;

### DETAILED DESCRIPTION OF THE ILLUSTRATED EMBODIMENTS

The present invention of the MEMS optical modulator with independently controlled with integrated ASIC device presents a new method for electrical connections and controls with a large number of control signals. With implementing attached ASIC control circuitry with MEMS structures by the use of wafer bonding technology, the present invention of the MEMS optical modulator with independently controlled with integrated ASIC device gives independent control for each micromirror in the MEMS optical modulator with multiple degrees of freedom motion. The present invention of the MEMS optical modulator with independently controlled with integrated ASIC device is described in detail for how to build, to configure, and to operate.

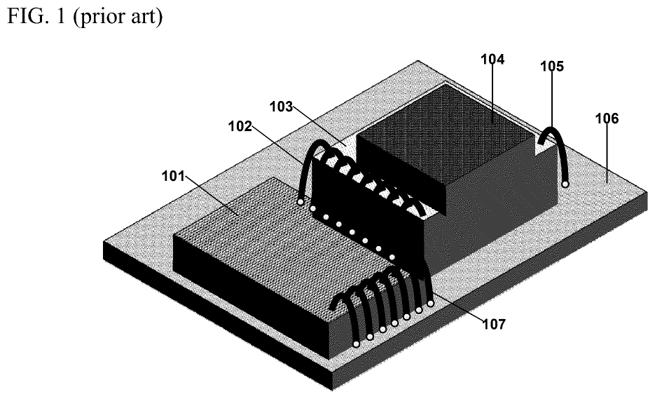

FIG. 1 (prior art) shows the typical system configuration where MEMS optical modulator and control logic circuit ICs (prior art). The MEMS optical modulator (structures) 104 are fabricated on a MEMS wafer substrate 103 by use of MEMS and semiconductor processes. To establish a connection with the control logic circuit 101, the MEMS wafer substrate 103 is attached onto packaging PCB 106 of the final package together with the control logic circuit 101. In order to control the MEMS optical modulator 104, connections between the control logic circuit 101 and the MEMS optical modulator 104 is necessary. The bonded wires 102 between the control logic circuit 101 and the MEMS optical modulator 104 supply control signals and power to MEMS optical modulator 104. Separate wire bonding 105 can be carried out to supply independent power or signal to the MEMS optical modulator 104. For control by using a PC or a controller, external wire bonding 107 is performed to supply control signal data and power from external source and controller. Further connectors can be installed through the packaging PCB 106.

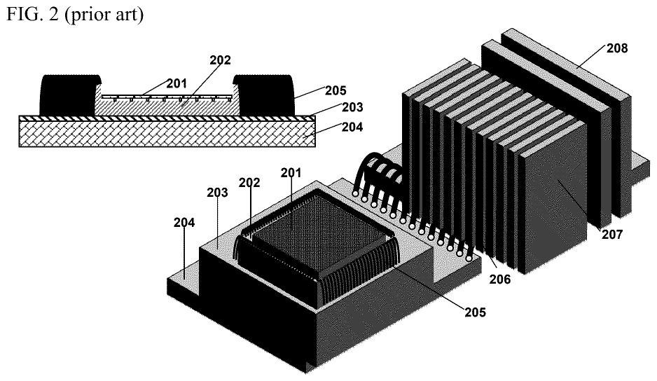

FIG. 2 (prior art) shows a more complex wire bonding structure including MEMS optical modulators 202 with MEMS structures (here micromirror array) 201, MEMS control device (CMOS logic circuit) 203, and multiple controller ICs 208. The MEMS structures 201, consisting of hundreds to thousands of micromirrors 201 to be controlled independently, is fabricated on a MEMS optical modulator (wafer level) 202. The fabricated and diced MEMS optical modulator 202 is bonded onto packaging PCB 204, together with MEMS control device 203 (here mostly ASIC control device). Wire bonding 205 is performed between the MEMS optical modulator 202 and MEMS control device 203 to provide control signal to the individual MEMS structures 201 through the MEMS optical modulator 202 input connections. Also for MEMS control device 203, there can be more control logic device such as driver ICs 207 and controller ICs 208. The integrated MEMS optical modulator 202 and MEMS control device 203 are connected with driver ICs 207 and controller ICs 208 through the external wire bonding or connector 206. Control signal data and power from an external source can be deliver through this external wire bonding or connector 206.

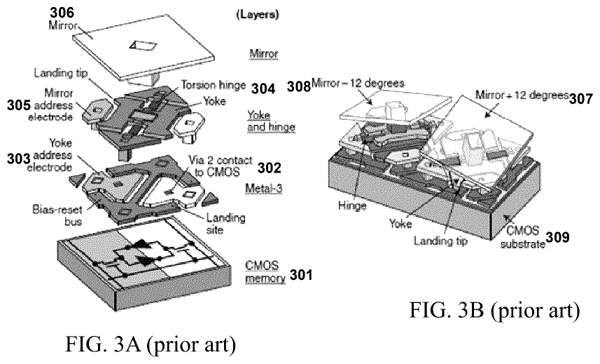

FIG. 3A (prior art) shows a layer schematic diagram of the DMD device from Texas Instrument. First CMOS memory 301 is built through standard semiconductor process. And then micromirror structures (yoke address electrodes 303, torsion hinge 304, mirror address electrodes 305, and mirrors 306) were built on top of the CMOS memory structures. The yoke address electrodes 303 and mirror address electrodes 305 are electrically connected to the CMOS memory through Via 302.

FIG. 3B (prior art) shows structure of Texas Instrument DMD device operation schematics. The individual micromirrors are operated with +/−12 degree rotation 307, 308 through the applied voltage from the CMOS substrate 309. Also the hinge structure 304 gives torsional restoration force for coming back to the original position.

One of the good examples of individually controlled micromirror device is Micromirror Array Lens. The general properties of the Micromirror Array Lens are disclosed in U.S. Pat. No. 7,173,653 issued Feb. 6, 2007 to Gim, U.S. Pat. No. 7,215,882 issued May 8, 2007 to Cho, U.S. Pat. No. 7,354,167 issued Apr. 8, 2008 to Cho, U.S. Pat. No. 9,565,340 issued Feb. 7, 2017 to Seo, U.S. Pat. No. 7,236,289 issued Jun. 26, 2007 to Back, U.S. Pat. No. 9,736,346 issued Aug. 15, 2017 to Back, all of which are incorporated herein by references.

The general principle, methods for making the micromirror array devices and Micromirror Array Lens, and their applications are disclosed in U.S. Pat. No. 7,057,826 issued Jun. 6, 2006 to Cho, U.S. Pat. No. 7,339,746 issued Mar. 4, 2008 to Kim, U.S. Pat. No. 7,077,523 issued Jul. 18, 2006 to Seo, U.S. Pat. No. 7,068,416 issued Jun. 27, 2006 to Gim, U.S. Pat. No. 7,333,260 issued Feb. 19, 2008 to Cho, U.S. Pat. No. 7,315,503 issued Jan. 1, 2008 to Cho, U.S. Pat. No. 7,768,571 issued Aug. 3, 2010 to Kim, U.S. Pat. No. 7,261,417 issued Aug. 28, 2007 to Cho, U.S. Pat. Pub. No. 2006/0203117 A1 published Sep. 14, 2006 to Seo, U.S. Pat. Pub. No. 2007/0041077 A1 published Feb. 22, 2007 to Seo, U.S. Pat. Pub. No. 2007/0040924 A1 published Feb. 22, 2007 to Cho, U.S. Pat. No. 7,742,232 issued Jun. 22, 2010 to Cho, U.S. Pat. No. 8,049,776 issued Nov. 1, 2011 to Cho, U.S. Pat. No. 7,350,922 issued Apr. 1, 2008 to Seo, U.S. Pat. No. 7,605,988 issued Oct. 20, 2009 to Sohn, U.S. Pat. No. 7,589,916 issued Sep. 15, 2009 to Kim, U.S. Pat. Pub. No. 2009/0185067 A1 published Jul. 23, 2009 to Cho, U.S. Pat. No. 7,605,989 issued Oct. 20, 2009 to Sohn, U.S. Pat. No. 8,345,146 issued Jan. 1, 2013 to Cho, U.S. Pat. No. 8,687,276 issued Apr. 1, 2014 to Cho, U.S. Pat. Pub. No. 2018/0164562 A1 published Jun. 14, 2018 to Byeon, U.S. Pat. Pub. No. 2019/0149795 A1 published May 16, 2019 to Sohn, U.S. Pat. Pub. No. 2019/0149804 A1 published May 16, 2019 to Sohn, U.S. Pat. Pub. No. 2020/0341260 A1 published Oct. 29, 2020 to Gaiduk, U.S. Pat. No. 11,378,793 issued Jul. 5, 2022 to Winterot, U.S. Pat. Pub. No. 2021/0132356 A1 published May 6, 2021 to Gaiduk, all of which are incorporated herein by references.

The general principle, structure and methods for making the discrete motion control of MEMS device are disclosed in U.S. Pat. No. 7,330,297 issued Feb. 12, 2008 to Noh, U.S. Pat. No. 7,365,899 issued Apr. 29, 2008 to Gim, U.S. Pat. No. 7,382,516 issued Jun. 3, 2008 to Seo, U.S. Pat. No. 7,400,437 issued Jul. 15, 2008 to Cho, U.S. Pat. No. 7,411,718 issued Aug. 12, 2008 to Cho, U.S. Pat. No. 7,474,454 issued Jan. 6, 2009 to Seo, U.S. Pat. No. 7,488,082 issued Feb. 10, 2009 to Kim, U.S. Pat. No. 7,535,618 issued May 19, 2009 to Kim, U.S. Pat. No. 7,898,144 issued Mar. 1, 2011 to Seo, U.S. Pat. No. 7,777,959 issued Aug. 17, 2010 to Sohn, U.S. Pat. No. 7,589,884 issued Sep. 15, 2009 to Sohn, 2006, U.S. Pat. No. 7,589,885 issued Sep. 15, 2009 to Sohn, U.S. Pat. No. 7,605,964 issued Oct. 20, 2009 to Gim, and U.S. Pat. No. 9,505,606 issued Nov. 29, 2016 to Sohn, all of which are incorporated herein by references.

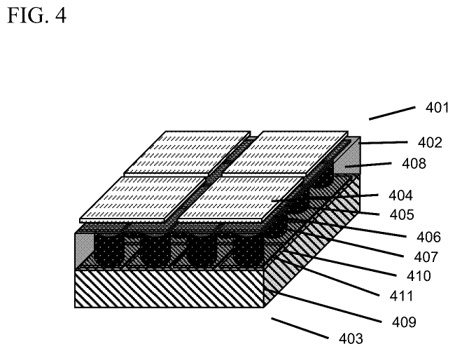

FIG. 4 illustrates the bonded structure of the MEMS optical modulator 401 and the ASIC device 403 and arranged with square shape micromirror 404 geometry wherein the MEMS electrodes 406 and the ASIC electrodes 411 are aligned with each other. FIG. 4 shows the wafer bonded MEMS optical modulator 401 wherein the MEMS optical modulator 401 has two devices bonded together with wafer bonding technology. One is the micromirror array device 402 having micromirrors 404, actuators 405, MEMS electrodes 406 and TSVs 407 on the MEMS substrate 408 and the other is the ASIC device 403 having ASIC substrate 409, electronics (not shown) 410, and ASIC electrodes 411 together with square type micromirrors 404 and MEMS electrodes 406.

The wafer bonded structures (the MEMS optical modulator 401) in wafer level are diced later after fabricating the all the structures. The structures should be dices separately for the micromirror array device 402 and the ASIC device 403. Especially the ASIC device 403 should have the exposed electrical pads for the external connections for the data/command communication and the power supply. The process for making device with the split dicing is disclosed in U.S. patent application Ser. No. 18/394,866 by Hong, which is incorporated herein by references.

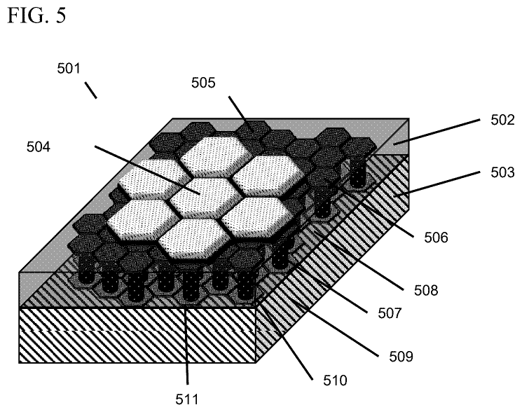

FIG. 5 illustrates the bonded structure of the MEMS optical modulator 501 with the micromirror array device 502 and the ASIC device 503 which are arranged with hexagonal shape micromirror 504 geometry wherein the MEMS electrodes 506 and the ASIC electrodes 511 are aligned with each other. FIG. 5 shows the wafer bonded MEMS optical modulator 501 having two devices bonded together with wafer bonding technology. One is the micromirror array device 502 having micromirrors 504, actuators 505, MEMS electrodes 506 and TSVs 507 on the MEMS substrate 508 and the other is the ASIC device 503 having ASIC substrate 509, electronics (not shown) 510, and ASIC electrodes 511 together with hexagonal type micromirrors 504 and MEMS electrodes 506.

The wafer bonded structures of MEMS optical modulator 501 in wafer level are diced after fabrication. The structures should be diced separately for the micromirror array device 502 and the ASIC device 503. Especially the ASIC device 503 should have the exposed electrical-pads for the external connections for the data/command communication and the power supply. The ASIC device 503 has two sections of the ASIC electrodes 511 and the electro-pads for communication. The ASIC electrodes are for the micromirror array device 502 and the electrical pads are for communication to the external devices such as MCU, computer through communication protocols. The process for making device with the split dicing is for exposing the exposed electro-pads disclosed in U.S. patent application Ser. No. 18/394,866 by Hong, which is incorporated herein by references.

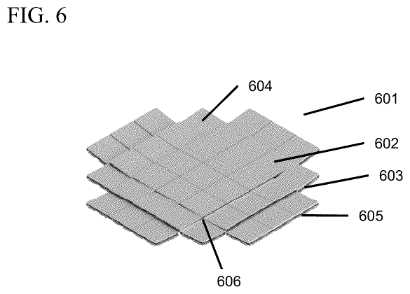

FIG. 6 shows an example of modulated surface profile 606 for the present invention of the MEMS optical modulator 601. To generate the modulated surface profile 606, first the ASIC device 603 receives control signal from outside (MCU or CPU from computer). Second, the ASIC device 603 translates the control commands to generate frame data for the modulated surface profile 606 in the memory of the ASIC device 603 (internal or external, mostly internal). Based on the modulated surface profile 606 data, the ASIC device 603 generates the control voltages of the individual ASIC electrodes while generating the column and row drivers switch the rows and column data for the whole frame of the data.

After generating the control voltages for the actuators in the micromirror array device 602, the control voltages are transferred through the TSVs to the MEMS electrodes in the micromirror array device 602. Finally, individual actuators 605 are operated with the control voltages and generate motions of the individual micromirrors 604. These individual micromirror 604 motions generate the modulated surface profile 606 and the modulated surface profiles 606 are used for optical surface in the optical system to control the lights. And by control commands from MCU or CPU, the ASIC device 603 generates multiple modulated surface profiles 606 based on signals from the control devices (MCU, CPU or etc.) to control light in the optical system. After generating (while generating) the modulated surface profile, the ASIC device 603 receive next frame data to have better efficiency of the control line. And while not receiving new modulated surface profile 606, the ASIC device 603 uses the data already received and stored in the memory to refresh the modulated surface profile 606. The FIG. 6 shows an example of the modulated surface profiles 606.

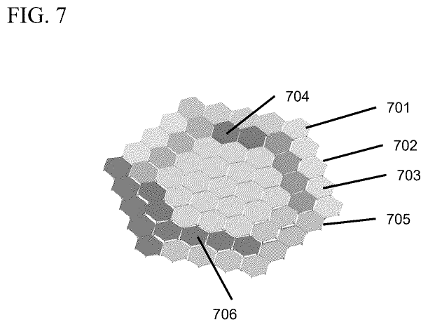

FIG. 7 shows an example of modulated surface profile 706 for the present invention of the MEMS optical modulator 701 with independently controlled with integrated ASIC device 703. Differently from the case of the FIG. 6, the modulated surface profile 706 is generated with hexagonal micromirrors 704. Different addressing for the device and geometry is applied for the system. To generate the modulated surface profile 706, first the ASIC device 703 receives control signal from outside (MCU or CPU from computer). Second, the ASIC device 703 translates the control commands to generated frame data for the modulated surface profile 706 in the memory of the ASIC device 703 (internal or external, mostly internal). Based on the modulated surface profile 706 data, the ASIC device 703 generates the control voltages of the individual ASIC electrodes while generating the column and row drivers switch the rows and column data for the whole frame of the data.

After generating the control voltages for the actuators in the micromirror array device 702, the control voltages are transferred through the TSVs to the MEMS electrodes in the micromirror array device 702. Finally, individual actuators 705 are operated with the control voltages and generate motions of the individual micromirrors 704. These individual micromirror 704 motions generate the modulated surface profile 706 and the modulated surface profiles 706 are modulating the optical properties of the optical system. And by control commands from MCU or CPU, the ASIC device 703 generates continuous modulated surface profiles 706 to vary the optical properties based on feedback of the optical system (or control parameter of the optical system). The FIG. 7 shows an example of the modulated surface profiles 706 with hexagonal micromirror array configuration.

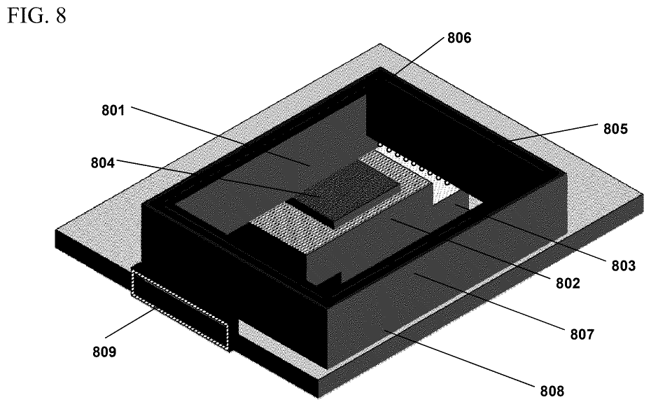

FIG. 8 shows an example of 3D packaging model of for the MEMS optical modulator 801 with independently controlled with integrated ASIC device 803. The MEMS optical modulator 801 has two parts with the micromirror array device 802 and the ASIC device 803. The micromirror array device has the optical effective area 804 which have the plurality of the micromirrors to control individual lights. Each micromirror has multiple actuators for controlling the multiple degrees of motion for the MEMS optical modulator 801. The micromirror array device 802 and the ASIC device 803 are connected through the substrate of the micromirror array device 802 with TSV structures. The ASIC device 803 has control through the wire bonding 805 from the packaging PCB 808 to the ASIC device 803. To protect the micromirror structure (optical effective area 804), optical cover 806 are places with shim structure 807 from the packaging PCB 808. Optionally and finally the control lines are connected through the connector 809 to external control system. The present invention of the MEMS optical modulator 801 with independently controlled with integrated ASIC device 803 has advantage of the independently control of the actuators in the micromirror array device 802. Basically to have independent control, the same numbers of connection (wire bonding) is required to the MEMS optical modulators if MEMS optical modulator 801 has the control circuitry inside, which are usually difficult to configure due to MEMS process and the semiconductor process are not compatible. The present invention of the MEMS optical modulator 801 with independently controlled with integrated ASIC device 803 removed this wire bonding structure and simplified the structure of the system.

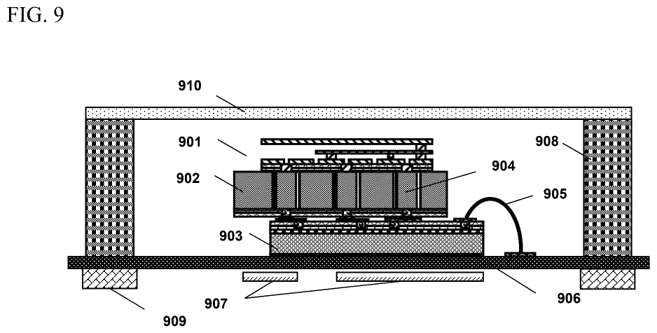

FIG. 9 shows the cross-sectional packaging structure of the MEMS optical modulator 901 with independently controlled with integrated ASIC device 903. The MEMS optical modulator 901 has two parts with the micromirror array device 902 and the ASIC device 903. The micromirror array device 902 has connecting structures through the substrate of the micromirror array device 902 with TSVs 904. TSVs 904 have the conducting structures surrounded by the insulating areas for the channels not to be shorted each other. And the ASIC device 903 has a plurality of the electrodes wherein the electrodes are fed with independently generated voltage signals from the ASCI device 903 and transferred to the micromirror array device 902 through TSVs 904.

To have individual device package, the effective area of the MEMS optical modulator 901 should be protected and the required electrical signal should be delivered to the MEMS optical modulator 901. To protect the effective area of the fragile MEMS optical modulator 901, optical cover glass 910 is attached to the packaging PCB 906 with help of ship structure 908. The ASIC device has control output through the wire-bonding structure 905, wherein the wire-bonding structure delivers the required electrical signal to the MEMS optical modulator 901. For packaging, additional electrical components 907 such as power voltage converter, external memory device and so on are attached on the other side of the packaging PCB 906 not to fill too much space of the optical effective area side. Additionally, the packaging PCB 906 comprises electrical connectors 909 to the external control system.

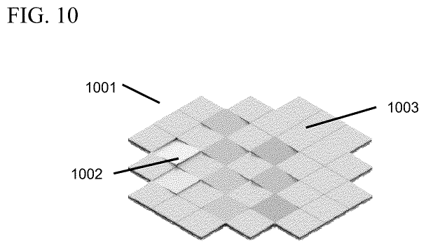

FIG. 10 shows simple operation of the MEMS optical modulator 1001. As seen in the FIG. 10, some micromirrors have motion with angle (independently tuned) and some have flat motion of the micromirrors. Motioned micromirrors 1002 can be seen as tilted about with other flat micromirrors. Also flat motion micromirrors 1003 have similar motions with null motion, which is the initial of the null operation mode. Here in the FIG. 10, all micromirrors are arranged with square type, which also can be modulated with square type structure of the ASIC electrodes device.

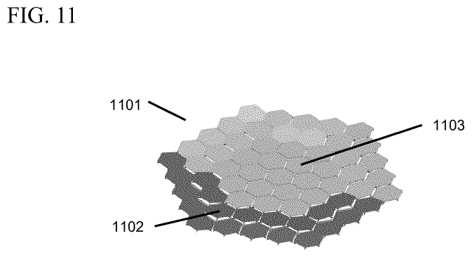

FIG. 11 shows simple operation of the MEMS optical modulator 1101 with hexagonal micromirrors. As seen in the FIG. 11, some micromirrors have motion with angle (independently tuned) and some have flat motion of the micromirrors. Motioned micromirrors 1102 can be seen as tilted about with other flat micromirrors. Also flat motion micromirrors 1103 have similar motions with null motion, which is the initial of the null operation mode. Here in the FIG. 10, all micromirrors are arranged with square type, which also can be modulated with the hexagonal micromirror type structure of the ASIC electrodes device.

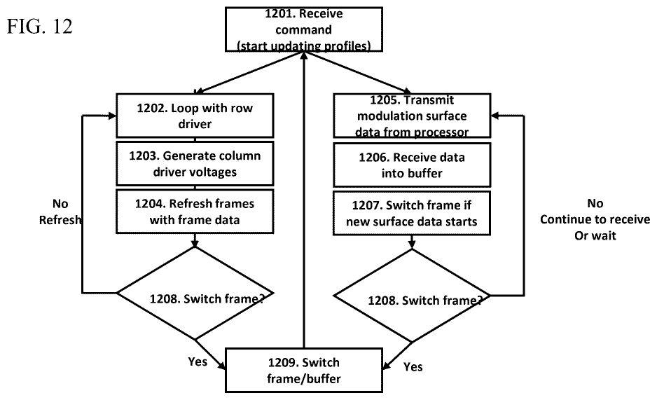

FIG. 12 illustrates control steps of the MEMS optical modulator wherein data receiving and refreshing frame are performed in parallel. The operation speed of the ASIC device and the data transfer can be synchronized but sometimes it is difficult to match. For the cases, the ASIC in the MEMS optical modulator can utilize the ping-pong scheme for efficient data transfer and generating the control voltages. When the MEMS optical modulator receives command 1201 from the control unit (MCU, CPU or control systems), the control steps for operating the MEMS optical modulator starts. At first the control system (MCU, CPU or control systems) transmit modulation surface data 1205. The ASIC device receives data 1206 into buffer (one of the ping-pong buffer) until one frame is done for receiving data. Once the ASIC finishes receiving data 1206 process, it sets the reading finish flag and wait for the switch frame 1208 signal from the control system or switch frame if new surface data starts 1207. Once switch frame 1208 command signal is received, the ASIC device change its buffer in the second ping-pong buffer and start receiving next frame data. And while receiving new frame data in the second ping-pong buffer, with the data in the first ping-pong buffer, the ASIC device starts making voltages. For making control voltages, the ASIC device starts loop with row driver 1202. Thus the row drivers operate the column drivers with increasing the index for the row drivers. While looping with row drivers 1202, the ASIC device generates column driver voltages 1203 for scanning the row drivers. When the whole row drivers are scanned, one frame of the data is sent to the MEMS optical modulator. When the frame data is done, the ASIC device starts refreshing frame 1204 with the data in the ping-pong buffer until it has switch frame 1208 control command. With the ping-pong buffer, one ping-pong buffer is used to generate voltages for operating the MEMS optical modulator. And the second ping-pong buffer is used to receive frame data for the new frame of the MEMS optical modulator. Once receiving the frame data process is done, ping-pong buffer is toggled each other for changing its rolls for switch frame/buffer 1209. This process is performed until the stop signal is received.

Most important for this process is that receiving data from process and generating (refreshing) the frame is both processed together in parallel. The ASIC device does not have to wait until new data is transferred into the ASIC device and refreshing which should be performed all the time to maintain the control voltages is performed at the same time and only when the new data is fully transferred, the frame can be changed with no delay.

The present invention of the MEMS optical modulator with independently controlled with integrated ASIC device comprises a) a micromirror array device wherein the micromirrors in the micromirrors array device are arranged to form a MEMS spatial light modulator, wherein each said micromirror is controlled individually and independently and each said micromirror has multiple degrees of freedom motion for spatial light modulation; b) a plurality of actuators for the micromirror array device wherein each said micromirror has the multiple actuators for multiple degrees of freedom motion; c) a substrate for the micromirror array device based on MEMS technology wherein the actuators and the micromirrors in the micromirror array device are fabricated on the substrate for the micromirror array device and wherein the substrate of the micromirror array device has a plurality of connecting means through the substrate of the micromirror array device from the one side of the substrate to the other side of the substrate; d) a plurality of MEMS electrodes wherein the plurality of the MEMS electrodes has correspondence with the plurality of the actuators and the plurality of the MEMS electrodes are arranged on one side of the substrate of the micromirror array device to control the plurality of the actuators in the micromirror array device; c) an ASIC device with a plurality of ASIC electrodes connected to the MEMS electrodes through the connecting means wherein the ASIC device is bonded with the micromirror array device in wafer-level while fabricating, wherein control voltages of the each ASIC electrodes in the ASIC device are generated independently in the ASIC device; and f) a plurality of electrical pad connections for powering and controlling the ASIC device and controlling the micromirrors in the micromirror array device.

The ASIC device and the micromirror array device is bonded with wafer-bonding technology while fabricated where the ASIC electrodes from the ASIC device and the MEMS electrodes in the micromirror array device are connected through the connecting means and control voltages of the ASIC device are transferred to the MEMS electrodes independently.

The individual micromirrors in the micromirror array device of the present invention of the MEMS optical modulator with independently controlled with integrated ASIC device have multiple actuators to have multiple degrees of freedom motion wherein the multiple actuators are controlled individually and independently with the plurality of the MEMS electrodes.

The plurality of actuators in the micromirror array device of the present invention of the MEMS optical modulator with independently controlled with integrated ASIC device are actuated by electrostatic force induced by the plurality of the MEMS electrodes on the substrate of the micromirror array device.

The ASIC device of the present invention of the MEMS optical modulator with independently controlled with integrated ASIC device comprises control circuitry that generates the control voltages of said each ASIC electrode wherein the ASIC electrodes in the ASIC device are connected with the MEMS electrodes for the micromirror array device with the connecting means through the substrate of the micromirror array device.

The plurality of the electrodes, the actuators, and the micromirrors in the micromirror array device of the present invention of the MEMS optical modulator with independently controlled with integrated ASIC device are built with surface micromachining or bulk micromachining technology.

The substrate of the micromirror array device of the present invention of the MEMS optical modulator with independently controlled with integrated ASIC device is made of silicon (Si). The plurality of the connecting means of the present invention of the MEMS optical modulator with independently controlled with integrated ASIC device is made of TSVs (Through Silicon Via).

The ASIC device of the present invention of the MEMS optical modulator with independently controlled with integrated ASIC device comprises a plurality of column drivers and row drivers to generate large number of the control voltages for the ASIC electrodes wherein the column drivers generate sets of the control voltages for said each row driver and changed with time scan for whole active area of the MEMS optical modulator.

The micromirror array device and the ASIC device of the present invention of the MEMS optical modulator with independently controlled with integrated ASIC device are bonded together so that the MEMS electrodes in the micromirror array device and the ASIC electrodes in the ASIC device are connected with the connecting means.

The micromirror array device and the ASIC device of the present invention of the MEMS optical modulator with independently controlled with integrated ASIC device are diced after wafer-bonding process for the MEMS optical modulator with independently controlled with integrated ASIC device.

The plurality of the electrical pad connections for powering and controlling of the present invention of the MEMS optical modulator with independently controlled with integrated ASIC device are exposed to have electrical connections with wire-bonding to outside circuit or power supply.

The ASIC device of the present invention of the MEMS optical modulator with independently controlled with integrated ASIC device further comprises a memory device wherein the memory device stores data for the MEMS optical modulator with independently controlled with integrated ASIC device and for spatial light modulation.

The ASIC device of the present invention of the MEMS optical modulator with independently controlled with integrated ASIC device implements a ping-pong buffer to generate the control voltages and to receive data from outside control at the same time.

The micromirrors in the micromirror array device of the present invention of the MEMS optical modulator with independently controlled with integrated ASIC device are hexagonal, square or rectangular shape.

The present invention of the MEMS optical modulator with independently controlled with integrated ASIC device can be operated with a method for operating a MEMS optical modulator with independently controlled with integrated ASIC device comprising steps of a) receiving command from outside control system (MPU, CPU, memory, or control systems); b) looping with row drivers for generating control voltages for a frame; c) generating the control voltages with column drivers for each row in the looping with the row drivers; d) refreshing frame with frame data, wherein the frame data is refreshed until switch frame command is received with looping of the row drivers while generating voltages with the column drivers; e) receiving frame data from outside processor, wherein the received data are stored into buffer; f) setting ready flag when the frame data is all received for a frame, wherein the ready flag is indicating frame data is ready for generating the control voltages; and g) switching frames wherein if switch frame command is received, the buffer is controlled to use in the looping with row drivers to generate the control voltages for the frame received from the processor and the receiving data process is ready for receiving a new frame data into buffer.

The buffer of the present invention of the MEMS optical modulator with independently controlled with integrated ASIC device is a ping-ping buffer which can be used in the looping with row drivers process and the receiving data into the buffer process, wherein the looping with row drivers process and the receiving data into the buffer process are processed at the same time, wherein the switch frame is received, the buffer becomes frame data for the looping with row drivers and the frame data area for the looping with the row drivers becomes the buffer and the whole processes are repeated until operation is stopped or paused.

The ping-pong buffer of the present invention of the MEMS optical modulator with independently controlled with integrated ASIC device has at least two frame data for operating back and forth between the looping with the row drivers and the receiving into the buffer processes.

A timing generator is used for looping with the row drivers for of the present invention of the MEMS optical modulator with independently controlled with integrated ASIC device, wherein the column drivers generate the control voltages based on the timing generator signal for said each row drivers.

The frame data of the present invention of the MEMS optical modulator with independently controlled with integrated ASIC device is continuously refreshed while receiving new frame data to maintain the control voltages more close to the desired values and to avoid decay of the voltages. The switching frames process of the present invention of the MEMS optical modulator with independently controlled with integrated ASIC device is performed only when receiving process and the refreshing process are finished a frame. The switching frames process is performed only when receiving process and the refreshing process are finished.

The MEMS optical modulator of the present invention comprises a memory (internal or external) to have a plurality of the frame data and wherein the receiving process if performed from the memory to receive a frame data. The MEMS optical modulator of the present invention receives the frame data directly from the memory.

The MEMS optical modulator of the present invention is controlled by the ASIC device which is wafer-bonded with the micromirror array device in the MEM optical modulator. The ASIC device is controlled through the exposed bond-pads. The exposed bond-pads in the MEMS optical modulator of the present invention are used for delivering control signal and power for the ASIC device thus controlling the MEMS optical modulator. At the same time, the micromirror array device comprises bond-pads separately from the ASIC device wherein the bond-pads provide extra grounding, control or testing purposes.

The present invention of the MEMS optical modulator with independently controlled with integrated ASIC device comprises basic two parts: a micromirror array device wherein the micromirrors in the micromirrors array device are arranged to form a MEMS spatial light modulator and to modulate incident light from the reflective surface of the micromirror array and an ASIC device with a plurality of the control voltage outputs. The micromirror array device needs a plurality of the control electrodes (MEMS electrodes) to control multiple degrees of freedom motions for individual micromirrors in the micromirror array device. Those MEMS electrodes are fed with control voltages from the ASIC device, wherein the ASIC device makes a plurality of the control voltages and gives output to the plurality of the ASIC electrodes. These ASIC electrodes correspond to the MEMS electrodes (with virtually one-to-one correspondence) to feed the control voltages to the MEMS electrodes with connecting means. Since the control voltages are generated independently and the connection between the MEMS electrodes and the ASIC electrodes are independently connected, the MEMS electrodes, thus the micromirrors in the micromirror device can have independent control and individual motion for light modulation.

To connect the MEMS electrodes and the ASIC electrodes, a plurality of the connecting means through the substrate of the micromirror array device. The plurality of the connecting means is basically electrical connection through the holes of the substrate. TSVs are a good example for the connecting means. TSVs can provide connection from the top side of the substrate (MEMS structures, especially MEMS electrodes for actuators) to the bottom side of the substrate (connecting structures to the ASIC electrodes made during the process of the MEMS micromirror array device matching with ASIC electrode geometry). Also the ASIC electrodes are processed to have contact with the connecting structure of the bottom of the MEMS substrate. Then the ASIC electrodes and the MEMS electrodes are connected with one-to-one (not exactly) correspondence with wafer bonding. Wafer bonding can provide proper connections to the ASIC electrodes and the MEMS electrodes (connecting structures at the bottom of the MEMS substrate through TSVs from MEMS electrodes of the top of the MEMS substrate).

The connecting means like TSVs can be built from the beginning of the MEMS process (via first process) or at the last stage of the MEMS process (via last process). TSVs connecting the MEMS electrodes and the ASIC electrodes should have insulation around to prevent interference between electrodes to have independent controls. The present invention of the MEMS optical modulator with independently controlled with integrated ASIC device comprises a substrate of the micromirror array device wherein the substrate has a plurality of connecting means such as TSV structures.

For the micromirrors in the micromirror array device to have multiple degrees of freedom motion independently, the micromirror array device should comprise at least similar number of the actuators in the micromirror array device, preferably, each micromirror in the micromirror device comprises at least the same number of the actuators. The present invention of the MEMS optical modulator with independently controlled with integrated ASIC device comprises a plurality of actuators for the micromirror array device wherein each said micromirror has the multiple actuators for multiple degrees of freedom motion. To operates the individual actuators in the micromirror array device, the present invention of the MEMS optical modulator with independently controlled with integrated ASIC device comprises a plurality of the MEMS electrodes wherein the plurality of the MEMS electrodes has correspondence with the plurality of the actuators and the plurality of the MEMS electrodes are arranged on one side of the substrate of the micromirror array device to control the plurality of the actuators in the micromirror array device.

As mentioned before, the present invention of the MEMS optical modulator with independently controlled with integrated ASIC device comprises an ASIC device with a plurality of the ASIC electrodes connected to the MEMS electrodes through the connecting means wherein the ASIC device is bonded with the micromirror array device in wafer-level while fabricating. The ASIC device generates the control voltages of said each ASIC electrodes in the ASIC device independently in the ASIC device. With digital and analog circuitry inside the ASID device, the ASIC device generates a plurality of the control voltages to the ASIC electrodes. And the ASIC device is controlled through a plurality of electrical pad connections for powering and controlling the ASIC device and controlling the micromirrors in the micromirror array device. These plurality of the electrical pad connections should be exposed after the wafer bonding process to connect the ASIC electrodes and the MEMS electrodes. The exposed plurality of the electrical pad connections is built with split dicing method which is disclosed in U.S. patent application Ser. No. 18/394,866 by Hong, which is incorporated herein by references.

The ASIC device of the present invention of the MEMS optical modulator with independently controlled with integrated ASIC device comprises a plurality of column drivers and row drivers to generate large number of the control voltages for the ASIC electrodes wherein the column drivers generate sets of the control voltages for said each row driver and changed with time scan for whole active area of the MEMS optical modulator.

The micromirror array device and the ASIC device of the present invention of the MEMS optical modulator with independently controlled with integrated ASIC device are bonded together so that the MEMS electrodes in the micromirror array device and the ASIC electrodes in the ASIC device are connected with the connecting means.

The micromirror array device and the ASIC device of the present invention of the MEMS optical modulator with independently controlled with integrated ASIC device are diced after wafer-bonding process for the MEMS optical modulator with independently controlled with integrated ASIC device.

The micromirrors in the micromirror array device of the present invention of the MEMS optical modulator with independently controlled with integrated ASIC device are hexagonal, square or rectangular shape. The individual micromirror in the MEMS optical modulator with independently controlled with integrated ASIC device are controlled to have light modulation of the incident light. The MEMS optical modulator can change the light direction with tilt of the individual micromirrors in the MEMS optical modulator. The MEMS optical modulator can change the optical phase of the incident light with the translation motion of the individual micromirrors in the MEMS optical modulator. Each micromirror in the MEMS optical modulator is controlled to control the section of the incident light to modulate the incident light.

While the invention has been shown and described with reference to different embodiments thereof, it will be appreciated by those skills in the art that variations in form, detail, compositions and operation may be made without departing from the spirit and scope of the invention as defined by the accompanying claims.

This work was supported by the Industrial Technology Innovation Program (20026046) funded by the Ministry of Trade, Industry & Energy (MOTIE, Korea).

What is claimed is:

1. A MEMS optical modulator with independently controlled with integrated ASIC (Application Specific Integrated Circuit) device comprising:
a. a micromirror array device wherein the micromirrors in the micromirrors array device are arranged to form a MEMS (Micro-Electro Mechanical System) spatial light modulator, wherein each said micromirror is controlled individually and independently and each said micromirror has multiple degrees of freedom motion for spatial light modulation;
b. a plurality of actuators for the micromirror array device wherein each said micromirror has the multiple actuators for multiple degrees of freedom motion;
c. a substrate for the micromirror array device based on MEMS technology wherein the actuators and the micromirrors in the micromirror array device are fabricated on the substrate for the micromirror array device and wherein the substrate of the micromirror array device has a plurality of connecting means through the substrate of the micromirror array device from the one side of the substrate to the other side of the substrate;
d. a plurality of MEMS electrodes wherein the plurality of the MEMS electrodes has correspondence with the plurality of the actuators and the plurality of the MEMS electrodes are arranged on one side of the substrate of the micromirror array device to control the plurality of the actuators in the micromirror array device;
e. an ASIC device with a plurality of ASIC electrodes connected to the MEMS electrodes through the connecting means wherein the ASIC device is bonded with the micromirror array device in wafer-level while fabricating, wherein control voltages of the each ASIC electrodes in the ASIC device are generated independently in the ASIC device; and
f. a plurality of electrical pad connections for powering and controlling the ASIC device and controlling the micromirrors in the micromirror array device;
wherein the ASIC device and the micromirror array device is bonded with wafer-bonding technology while fabricated where the ASIC electrodes from the ASIC device and the MEMS electrodes in the micromirror array device are connected through the connecting means and control voltages of the ASIC device are transferred to the MEMS electrodes independently.

2. The MEMS optical modulator with independently controlled with integrated ASIC device in claim 1, wherein the individual micromirrors in the micromirror array device have multiple actuators to have multiple degrees of freedom motion wherein the multiple actuators are controlled individually and independently with the plurality of the MEMS electrodes.

3. The MEMS optical modulator with independently controlled with integrated ASIC device in claim 1, wherein the plurality of actuators in the micromirror array device are actuated by electrostatic force induced by the plurality of the MEMS electrodes on the substrate of the micromirror array device.

4. The MEMS optical modulator with independently controlled with integrated ASIC device in claim 1, wherein the ASIC device comprises control circuitry that generates the control voltages of said each ASIC electrode wherein the ASIC electrodes in the ASIC device are connected with the MEMS electrodes for the micromirror array device with the connecting means through the substrate of the micromirror array device.

5. The MEMS optical modulator with independently controlled with integrated ASIC device in claim 1, wherein the plurality of the electrodes, the actuators, and the micromirrors in the micromirror array device are built with surface micromachining or bulk micromachining technology.

6. The MEMS optical modulator with independently controlled with integrated ASIC device in claim 1, wherein the substrate of the micromirror array device is made of silicon (Si).

7. The MEMS optical modulator with independently controlled with integrated ASIC device in claim 1, wherein the plurality of the connecting means is made of TSVs (Through Silicon Via).

8. The MEMS optical modulator with independently controlled with integrated ASIC device in claim 1, wherein the ASIC device comprises a plurality of column drivers and row drivers to generate large number of the control voltages for the ASIC electrodes wherein the column drivers generate sets of the control voltages for said each row driver and changed with time scan for whole active area of the MEMS optical modulator.

9. The MEMS optical modulator with independently controlled with integrated ASIC device in claim 1, wherein the micromirror array device and the ASIC device are bonded together so that the MEMS electrodes in the micromirror array device and the ASIC electrodes in the ASIC device are connected with the connecting means.

10. The MEMS optical modulator with independently controlled with integrated ASIC device in claim 1, wherein the micromirror array device and the ASIC device are diced after wafer-bonding process for the MEMS optical modulator with independently controlled with integrated ASIC device.

11. The MEMS optical modulator with independently controlled with integrated ASIC device in claim 1, wherein the plurality of the electrical pad connections for powering and controlling are exposed to have electrical connections with wire-bonding to outside circuit or power supply.

12. The MEMS optical modulator with independently controlled with integrated ASIC device in claim 1, wherein the ASIC device further comprises of a memory device wherein the memory device stores data for the MEMS optical modulator with independently controlled with integrated ASIC device and for spatial light modulation.

13. The MEMS optical modulator with independently controlled with integrated ASIC device in claim 1, wherein the ASIC device implement ping-pong buffer to generate the control voltages and to receive data from outside control at the same time.

14. The MEMS optical modulator with independently controlled with integrated ASIC device in claim 1, wherein the micromirrors in the micromirror array device are hexagonal, square or rectangular shape.

15. A method for operating a MEMS optical modulator with independently controlled with integrated ASIC device comprising steps of:
a. receiving command from outside control system (MPU, CPU, memory, or control systems);
b. looping with row drivers for generating control voltages for a frame;
c. generating the control voltages with column drivers for each row in the looping with the row drivers;
d. refreshing frame with frame data, wherein the frame data is refreshed until switch frame command is received with looping of the row drivers while generating voltages with the column drivers;
e. receiving frame data from outside processor, wherein the received data are stored into buffer;
f. setting ready flag when the frame data is all received for a frame, wherein the ready flag is indicating frame data is ready for generating the control voltages; and
g. switching frames wherein if switch frame command is received, the buffer is controlled to use in the looping with row drivers to generate the control voltages for the frame received from the processor and the receiving data process is ready for receiving a new frame data into buffer;
wherein the buffer is a ping-ping buffer which can be used in the looping with row drivers process and the receiving data into the buffer process, wherein the looping with row drivers process and the receiving data into the buffer process are processed at the same time, wherein the switch frame is received, the buffer becomes frame data for the looping with row drivers and the frame data area for the looping with the row drivers becomes the buffer and the whole processes are repeated until operation is stopped or paused.

16. The method for operating a MEMS optical modulator with independently controlled with integrated ASIC device in claim 15, the ping-pong buffer is used and the ping-pong buffer has at least two frame data for operating back and forth between the looping with the row drivers and the receiving into the buffer processes.

17. The method for operating a MEMS optical modulator with independently controlled with integrated ASIC device in claim 15, a timing generator is used for looping with the row drivers, wherein the column drivers generate the control voltages based on the timing generator signal for said each row drivers.

18. The method for operating a MEMS optical modulator with independently controlled with integrated ASIC device in claim 15, the frame data is continuously refreshed while receiving new frame data to maintain the control voltages more close to the desired values and to avoid decay of the voltages.

19. The method for operating a MEMS optical modulator with independently controlled with integrated ASIC device in claim 15, wherein the switching frames process is performed only when receiving process and the refreshing process are finished a frame.

20. The method for operating a MEMS optical modulator with independently controlled with integrated ASIC device in claim 15, wherein the switching frames process is performed only when receiving process and the refreshing process are finished.

21. The method for operating a MEMS optical modulator with independently controlled with integrated ASIC device in claim 15, wherein the MEMS optical modulator comprises a memory (internal or external) to have a plurality of the frame data and wherein the receiving process if performed from the memory to receive a frame data.

22. The method for operating a MEMS optical modulator with independently controlled with integrated ASIC device in claim 21, wherein the MEMS optical modulator receives the frame data directly from the memory.
